(19) United States
(12) Patent Application Publication
(10) Pub. No.: US 2026/0045437 A1
(43) Pub. Date: Feb. 12, 2026

(54) FIELD CURVATURE CORRECTOR FOR USE IN MULTI-ELECTRON-BEAM OPTICAL SYSTEM

(71) Applicant: KLA Corporation, Milpitas, CA (US)

(72) Inventor: Xinrong Jiang, Palo Alto, CA (US)

(21) Appl. No.: 18/930,438

(22) Filed: Oct. 29, 2024

Related U.S. Application Data
(60) Provisional application No. 63/680,190, filed on Aug. 7, 2024.

(51) Int. Cl. H01J 37/09; H01J 37/153; H01J 37/244; H01J 37/28

(52) U.S. Cl. CPC H01J 37/09; H01J 37/153; H01J 37/244; H01J 37/28; H01J 2237/0453; H01J 2237/04928; H01J 2237/1205; H01J 2237/1532; H01J 2237/1534

(57) ABSTRACT

A multi-electron-beam (MEB) imaging system may include a field curvature corrector for individually correcting electron beamlets for field curvature blur by individually addressing microlenses of the field curvature corrector. The field curvature corrector may include a conductive plate, wherein the conductive plate includes a plurality of holes arranged in a hexagonal array. The field curvature corrector may include a microlens array, wherein the microlens array includes a plurality of microlenses formed on an insulative plate, wherein the plurality of microlenses are arranged in a hexagonal pattern to match the hexagonal pattern of the holes of the conductive plate. The microlens array includes a plurality of power lines for individually addressing each of the microlenses of the microlens array.

The present application claims the benefit under 35 U.S.C. § 119 (e) of U.S. Provisional Application Ser. No. 63/680,190, filed Aug. 7, 2024, which is incorporated herein by reference in the entirety.

### TECHNICAL FIELD

The present disclosure relates generally to multi-electron-beam (MEB) inspection systems and, more particularly, to MEB systems with field curvature corrector devices for correcting field curvature error at the individual beamlet level.

### BACKGROUND

Scanning electron beam inspection tools are commonly used in the semiconductor industry for inspection of semiconductor devices formed on semiconductor wafers. Commercially available electron beam-based inspection machines currently utilize a single electron beam column based on the principle of scanning electron microscopy. Low throughput is a significant obstacle in such machines because the images are acquired in a sequential pixel-by-pixel manner. In addition, the scan field-of-view (FOV) of a single electron beam is limited to tens of microns due to optical blur and distortion, while the translation of the sample stage necessary to inspect an integrated circuit die is approximately 1-10 millimeters. Large numbers of stage movements lower the throughput of the system severely, thereby significantly increasing inspection time and cost. To improve throughput of wafer inspection systems, multi-electron-beam machines have been developed. However, current multi-electron-beam systems face a tradeoff between the machine resolution and machine throughput. Multi-electron-beam systems include projection optics, in which field curvature blur is directly proportional to the second power of the field-of-view (FOV). The larger the FOV, the more electron beams that must be deployed. To maintain high resolution while improving the throughputs across a large FOV, the field curvature (FC) blur must be corrected. Currently, field curvature blur is corrected utilizing a collectively corrected methodology. The disadvantages of the method include a) degrading image resolutions due to introducing large spherical aberration blurs with high FC correction voltages, b) causing arcing risks with high electrical strengths across the FC corrector, and c) being unable to correct the asymmetrical FC blurs due to optical column misalignments. Therefore, it would be advantageous to provide a system that overcomes the challenges described above.

### SUMMARY

A multi-beam electron imaging system is disclosed, in accordance with one or more embodiments of the present disclosure. In some aspects, the multi-beam electron imaging system includes: an electron beam source configured to generate a telecentric primary electron beam; a micro-beam creation array configured to split the telecentric primary electron beam into a set of telecentric electron beamlets, wherein the micro-beam creation array includes: a field curvature corrector, wherein the field curvature corrector is configured to individually correct field curvature blur of each telecentric beamlet, wherein the field curvature corrector includes: a conductive plate, wherein the conductive plate includes a plurality of holes arranged in a hexagonal array; and a microlens array, wherein the microlens array includes a plurality of microlenses formed on an insulative plate, wherein the plurality of microlenses are arranged in a hexagonal pattern to match the hexagonal pattern of the holes of the conductive plate, wherein the microlens array includes a plurality of power lines for individually addressing each of the microlenses of the microlens array; and a set of electron optics configured to focus the set of telecentric electron beamlets onto a sample for inspection of the sample.

A multi-beam electron imaging system is disclosed, in accordance with one or more additional and/or alternative embodiments of the present disclosure. In some aspects, the multi-electron-beam imaging system includes: an electron beam source configured to generate a telecentric primary electron beam; a micro-beam creation array configured to split the telecentric primary electron beam into a set of telecentric electron beamlets, wherein the micro-beam creation array includes: a field curvature stack, wherein the field curvature stack includes a plurality of field curvature correctors, wherein each field curvature corrector includes: a conductive plate, wherein the conductive plate includes a plurality of holes arranged in a hexagonal array; and a microlens array, wherein the micro-lens array includes a plurality of microlenses formed on an insulative plate, wherein the plurality of microlenses are arranged in a hexagonal pattern to match the hexagonal pattern of the holes of the conductive plate, wherein each of the field curvature correctors includes one or more dummy portions and one or more active inspection areas of microlenses, wherein a stacked configuration of the plurality of field curvature correctors along a z-direction forms a contiguous active inspection area of microlenses along the x-direction and y-direction; and a set of electron optics configured to focus the set of telecentric electron beamlets onto a sample for inspection of the sample.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1 illustrates a simplified schematic view of an electron-optical architecture for a multi-electron-beam inspection system.

FIG. 2 illustrates a conceptual view of electron ray-tracing simulations to demonstrate the creation of multiple electron beams within a multi-electron-beam inspection system.

FIG. 3 illustrates a simplified schematic view of a field curvature corrector for correcting field curvature blur.

FIG. 4 illustrates a graph depicting the field curvature correction implemented with a field curvature corrector.

FIG. 5 illustrates a graph depicting the field curvature correction sensitivities.

FIG. 6 illustrates a Monte Carlo simulation of center beam spot size at a wafer when the field curvature corrector is applied with a voltage of 700 Volts.

FIG. 7 illustrates a Monte Carlo simulation of center beam spot size at a wafer when the field curvature corrector is applied with a voltage of 300 Volts.

FIG. 8A illustrates a simplified schematic view of a multi-beam electron imaging system incorporating a field curvature corrector, in accordance with one or more embodiments of the present disclosure.

FIG. 8B illustrates a schematic view of the field curvature corrector, in accordance with one or more embodiments of the present disclosure.

FIG. 8C illustrates a schematic top view of the conducive plate of the field curvature corrector, in accordance with one or more embodiments of the present disclosure.

FIG. 9 illustrates a schematic top view of the microlens array of the field curvature corrector, in accordance with one or more embodiments of the present disclosure.

FIG. 10 illustrates a schematic top view of the microlens array with power lines, in accordance with one or more embodiments of the present disclosure.

FIG. 11 illustrates a schematic top view of the microlens array showing the addressing of power lines, in accordance with one or more embodiments of the present disclosure.

FIG. 12 illustrates a schematic view of the field curvature corrector, in accordance with one or more additional and/or alternative embodiments of the present disclosure.

FIGS. 13A-13B illustrate simulations of electrostatic potentials to depict the avoidance of crosstalk between microlenses of the field curvature corrector, in accordance with one or more embodiments of the present disclosure.

FIGS. 14 and 15 illustrate a schematic top view and a schematic side view of a stack of field curvature correctors arranged aerially into multiple zones, in accordance with one or more additional and/or alternative embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

U.S. Pat. No. 11,651,934B2, issued on May 16, 2023, discusses a multi-electron-beam (MEB) system and is incorporated herein by reference in the entirety.

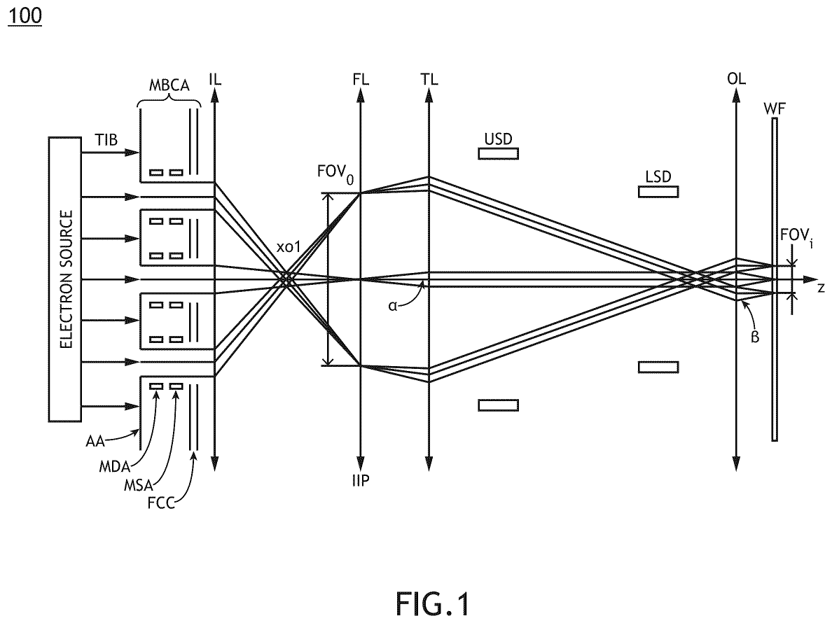

FIG. 1 illustrates an MEB inspection system. The electron source may be a conventional thermal field emission (TFE) with high brightness or high angular intensity (e.g., around 1.0 mA/sr). The source-emitted electrons with high total beam currents (e.g., tens of micro-amps) may be focused with a gun lens and/or collimated lens (not shown in FIG. 1) to form a telecentric illumination beam (TIB). An aperture array (AA) may be used to divide the large TIB into many small TIBs (telecentric illumination beamlets). These TIBs are then independently focused through a beam crossover of xo1 on an intermediate image plane (IIP) by a global imaging lens (IL). A global field lens (FL) may be used to adjust the directions of the multi electron beamlets. The principal plane of the field lens is deployed in the IIP plane for adjustment of the directions of the multibeams (without changing the image-forming aspect of each beamlet). A global transfer lens (TL) may be used to focus the multibeams and form a second beam crossover (xo2) around the back focal plane of the global objective lens (OL), and finally the OL image forms the multibeams on the wafer (WF). The optics from the IIP to the wafer may be projection optics characterized by an optical magnification (e.g., M=FOVᵢ/FOVₒ), and the multibeam array in the IIP may be evaluated with the optical magnification, M (e.g., around 0.125×). The multibeams may be collectively-scanned by the dual-deflector system consisting of the upper scan deflector (USD) and lower scan deflector (LSD). It is noted that a dual-deflector system has the advantage of lower deflection aberrations across a scan-field.

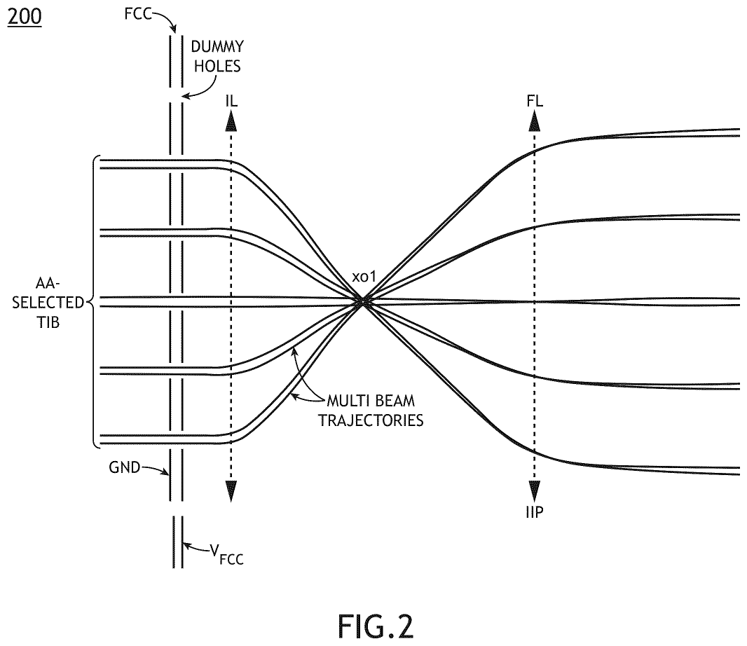

The manner of creation of the multibeams plays a critical role in meeting optical performance for both resolution and throughput. The micro-machined multi-beam creation array (MBCA) in FIG. 1 is utilized for creating multiple beams. The MBCA includes the aperture array (AA), the micro deflector array (MDA), the micro-stigmator array (MSA) and the field curvature corrector (FCC). The MBCA dimension ranges may be understood by describing the AA. The AA hole size may be tens of microns (e.g., 25˜40 μm) with a pitch (between holes) of hundreds of microns (e.g., 80˜120 μm). The aperture size selects the single beam current. The hole sizes for the MDA, MSA and FCC should all be larger than the aperture size. The multiple electron beams are created with MBCA and the image formed with the IL (image lens) and FL (field lens), as can be exhibited with computer ray-tracing simulations 200 shown in FIG. 2. The IL and FL may be global magnetic lenses with large sizes of pole piece bores. The geometric structures of the IL and FL are not shown in FIG. 2 because their (bore) sizes are much larger than the multiple beam sizes. According to the description provided in U.S. Pat. No. 11,651,934 B2, incorporated previously herein, the AA-selected TIBs are first separately defocused by the fields around the FCC bores and then collectively focused by the IL. Located in the center of the FL, the intermediate image plane (IIP) is the image plane of the multiple beams. A beam crossover (xo1) is formed because a global IL is used to image the multibeams.

It is noted that the off-axis blur and distortion for the off-axis beamlets in FIG. 1 and FIG. 2 are generated because of the IL deflections to those beamlets. The off-axis blur and distortion may be measured in the IIP or wafer. The distortion goes as the 3^{rd} power of the FOVₒ. The off-axis blurs include the coma (the coma is linear with respect to FOVₒ), field curvature (2^{nd} power with respect to FOVₒ), and astigmatism (the 2^{nd} power with respect to FOVₒ). It is additionally noted that the throughput of the MEB system is gated by the size of FOVₒ, or the number of electron beamlets when the pitch between the beams is fixed. For increasing the throughput with larger FOVₒ or more beams, the off-axis blurs must be removed (or corrected) in order to maintain the beamlet resolution.

The MSA (micro stigmator array) in FIG. 1 may be used to correct astigmatism. The MSA has been described in U.S. Pat. No. 11,056,312, granted on Jul. 6, 2021, which is incorporated herein by reference in the entirety.

The off-axis distortion sharply increases with the third power of FOVₒ, and it must be corrected for improving the machine throughput with larger FOVs. The MDA in FIG. 1 is used to correct the distortion. The MDA has been further described in U.S. Pat. No. 10,748,739, granted on Aug. 18, 2020, which is incorporated herein by reference in the entirety.

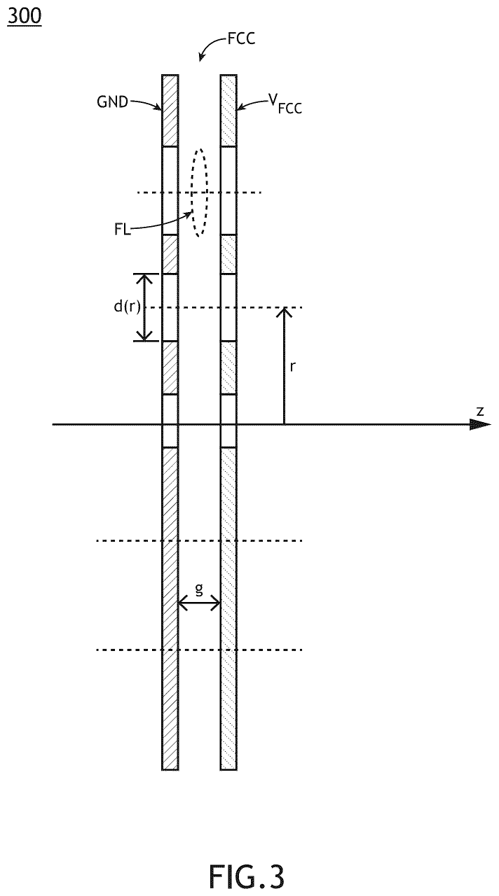

The FCC in FIG. 2 may be used to correct the FC blurs of the multibeams. FIG. 3 shows the schematic of the design for correcting the field curvatures. The FCC may include GND and V_{FCC} plates separated by a gap distance (g) of tens of microns. The thickness of the two conductive plates may be tens of microns as well. The bore sizes on the plates (d(r)) are varied as a function of off-axis distance r.

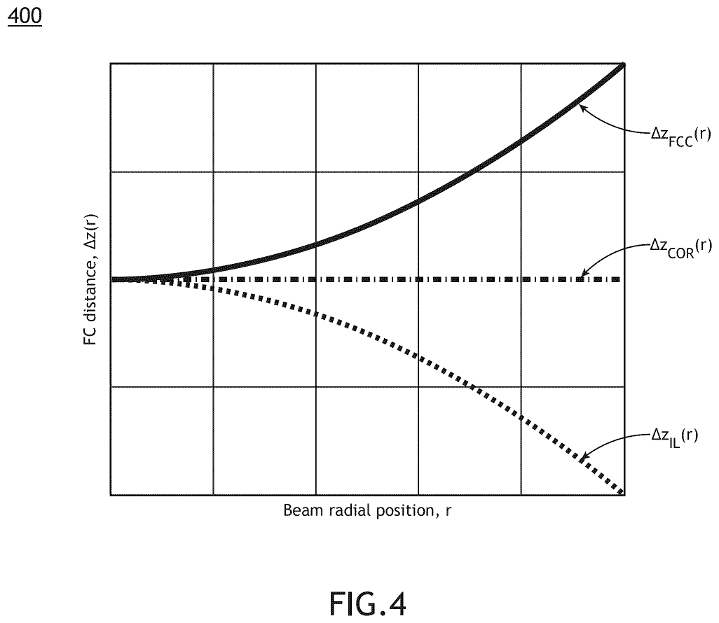

The correction of the field curvature blur is explained in FIGS. 2-4. According to the FC blur behavior, the beamlet FC distance at IIP, Δz_{IL}(r), is a negatively quadratic function of the off-axis position r (or the beam positions in r-direction), as shown in FIG. 4. When applying an FCC voltage V_{FCC} on the FCC plate, a micro focusing lens (FL) array is formed in between the GND and FCC plates, as shown in FIG. 3. The FCC bore sizes, d(r), in FIG. 3 are designed as quadratic distributions, such that the beamlet imaging points at IIP, Δz_{FCC}(r), are quadratically varied with respect to the beam positions (r), as shown in FIG. 4. With a proper FCC voltage V_{FCC}, the Δz_{FCC}(r) compensates to the Δz_{IL}(r), and the combined FC distance at IIP, Δz_{COR}(r), becomes zero to reach the complete correction of the field curvatures.

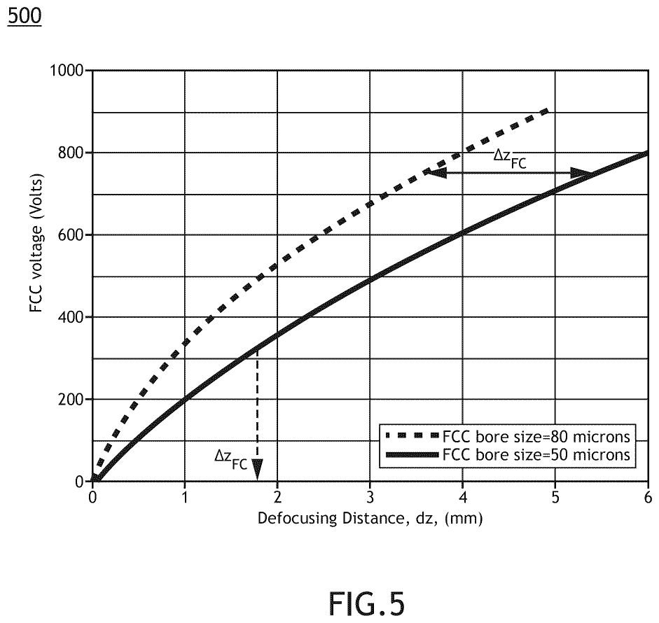

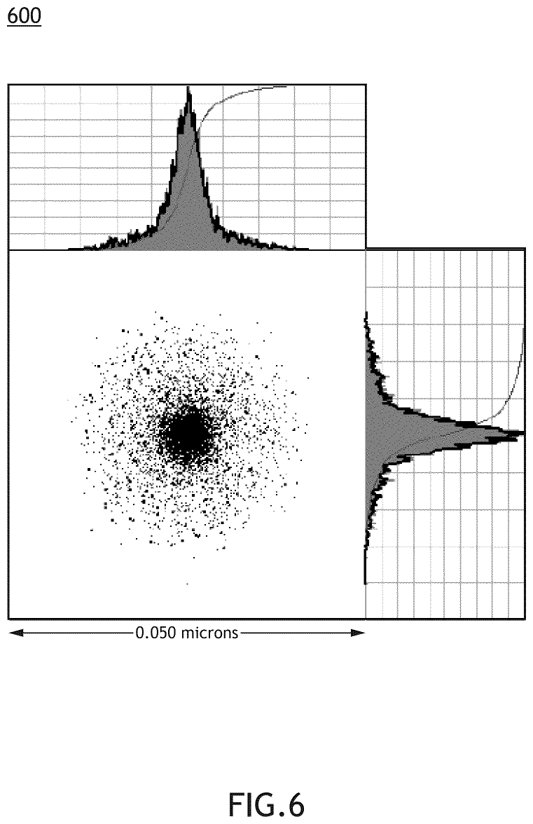

The FC correction via the previous method described above may be considered collective correction, in which only one correction voltage, V_{FCC}, is used for removing all FC blurs of all beamlets. However, such an FC-collectively-corrected method has multiple disadvantages. To correct a quadratic FC distance, the bore sizes on the FCC plates, d(r), are quadratically-varied with the beamlet off-axis distance r, as shown in FIG. 3. For example, taking a 100-micron pitch between beamlets, the center FCC bore size may be d(0)=50 microns, and the farthest (r=1000 microns) FCC bore size may be d(1000)=80 microns (assuming a total 331 beamlets in a hexagon distribution). The FCC sensitivity may be simulated at the IIP according to the operation conditions with the optics in FIG. 1. FIG. 5 shows the simulated FCC sensitivities. Given a maximum FC distance between the center beam and farthest beam, Δz_{FC} (e.g. 1.5 mm), the FCC voltage may be determined in FIG. 5. For example, the FCC voltage may be 700 Volts to completely correct the field curvatures of all beamlets. Because of the low FCC sensitivity with the FC-collectively-corrected method, the following disadvantages exist. First, a 700V FCC voltage is fairly high across a tens-of-micron gap between the GND and FCC plates, and arcing risks may occur. Second, the micro focusing lenses (FL in FIG. 3) with a 700V FCC voltage may generate severe spherical aberration blurs. The center beam may suffer the strongest spherical blur because the FCC bore size is smallest (e.g., 50 microns). FIG. 6 shows a Monte Carlo simulation of the center beam spot size at the wafer when a 700V FCC voltage is applied. The spot size of 4.9 nm in a 20-80% current-rise measurement is strongly dominated by the spherical aberration blur, compared to the spot size of 2.3 nm when an FCC voltage of zero volts is applied.

If the MEB optical column in FIG. 1 is mechanically aligned with all optical components, the FC-collectively-corrected method may be theoretically good at correcting rotationally symmetrical field curvatures. However, if the column experiences sufficient misalignments, the field curvatures are no longer rotationally symmetrical, even if column aligning systems are applied. A collective correction to asymmetrical field curvatures is unlikely to remove all FC blurs for all beamlets. Residual asymmetrical FC blurs will likely persist.

The FC-collectively-corrected method described in FIGS. 3-5 may be acceptable for an MEB system with a smaller number of beamlets, in which the low FCC sensitivity issue would not cause a dominant spherical blur with a relatively lower FCC voltage. With an increasing desire of higher throughputs with more electron beamlets, the FC distance between the center beam and farthest beam (i.e., Δz_{FC} in FIG. 5) would be increased significantly (increases as the 2^{nd} power to FOVₒ). In this case, the two disadvantages previously noted would be intolerable.

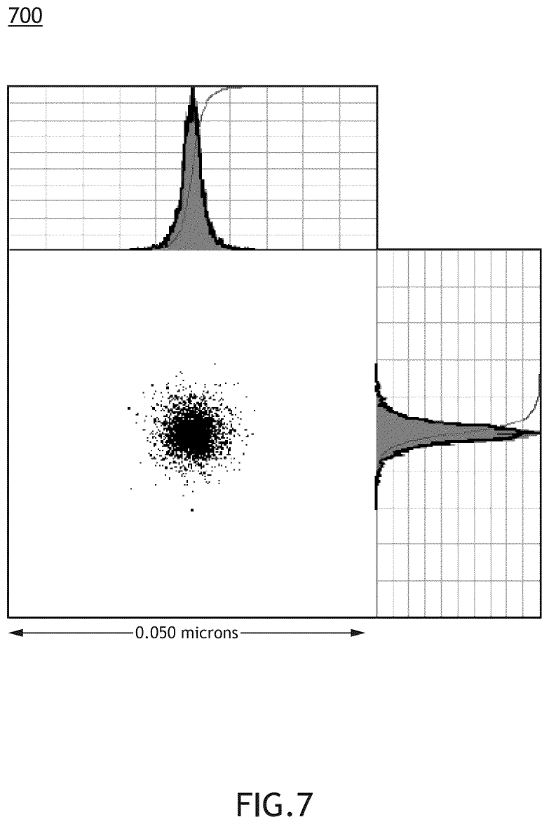

Accordingly, an FC-individually-corrected method is proposed. In FIG. 3, for example, it may be assumed all FCC bore sizes are equal (i.e., d(r)=constant (e.g., 50 microns, being equal to the center bore size)). Furthermore, it may be assumed that each beamlet FC is individually corrected by a separate microlens (the FL in FIG. 3) with a separate FCC voltage. In this approach, each micro-FL has the same FCC sensitivity as the solid-blue plot in FIG. 5. With the same correction for an FC distance of Δz_{FC} in FIG. 5, the FC-individually-corrected method applies less than half of the voltage (300V) than the FC-collectively-corrected method (700V). With a 300V FCC voltage, re-simulating the center beam spot size with the same conditions as those for FIG. 6 provides a 2.6 nm resolution, as can be exhibited in FIG. 7. The spherical aberration blur is almost removed, and the spot size (2.6 nm) is now fairly close to that with a zero FCC voltage (2.3 nm).

Embodiments of the present disclosure are directed to a field curvature corrector that corrects field curvature blur on an individual beam-by-beam basis. The advantages of the approach of the present disclosure include a) removing spherical aberration blur generated by the FC corrector due to using >2× lower FC correction voltage than previous methods; b) removing arcing risks due to using >2× lower FC correction voltages; and c) correcting all FCs (both symmetrical and asymmetrical FCs) due to the FC from each beamlet being individually corrected with an independent voltage.

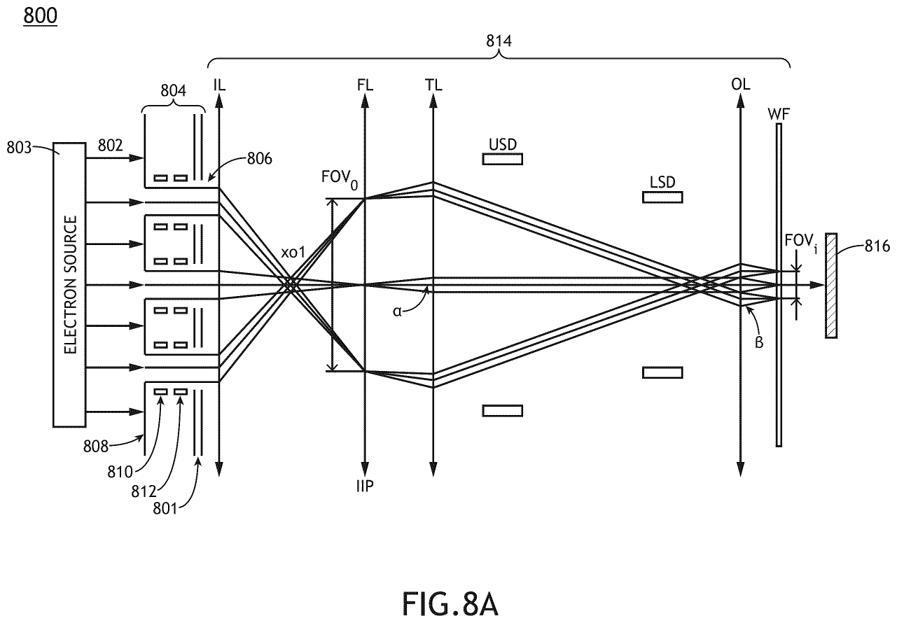

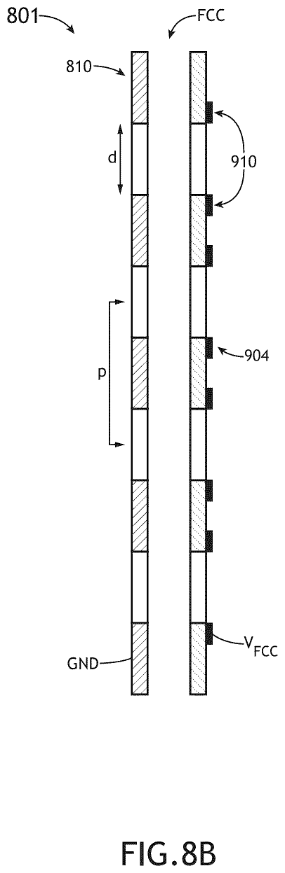

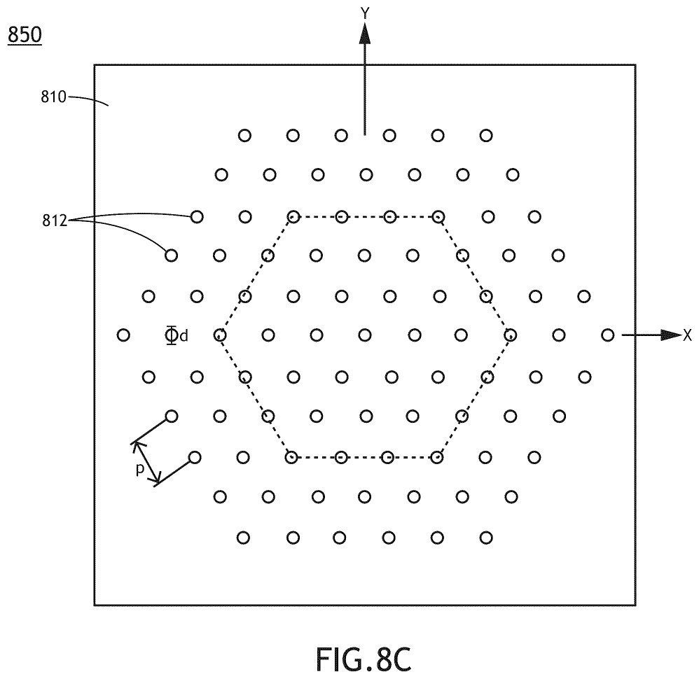

FIG. 8A illustrates a simplified schematic view of an MEB imaging system 800 incorporating a field curvature corrector 801, in accordance with one or more embodiments of the present disclosure. In embodiments, the MEB imaging system 800 includes an electron beam source 803 configured to generate a telecentric primary electron beam 802. In embodiments, the MEB imaging system 800 includes a micro-beam creation array (MBCA) 804 configured to split the telecentric primary electron beam 802 into a set of telecentric electron beamlets 806. The MBCA 804 may include, but is not limited to, an aperture array (AA) 808, a micro deflector array (MDA) 810, a micro stigmator array (MSA) 812, and the field curvature corrector (FCC) 801. In embodiments, the MEB imaging system 800 includes a set of electron optics 814 configured to focus the set of telecentric electron beamlets 806 onto a sample 816 and collect/direct electrons from the sample 816 onto a detector assembly (e.g., detector array).

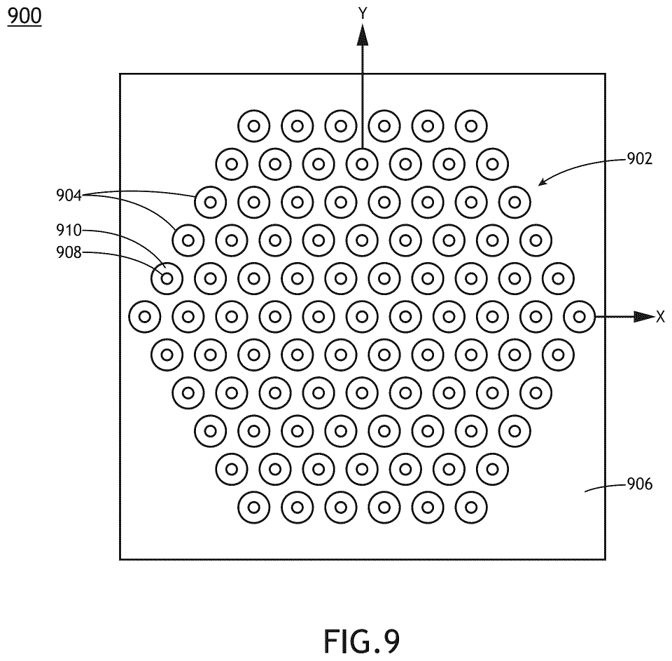

FIG. 8B illustrates a schematic view of the FCC 801, in accordance with one or more embodiments of the present disclosure. In embodiments, the FCC 801 allows for field curvature correction of the individual beamlets 806. In embodiments, the FCC 801 includes a conductive ground plate 810 (see FIG. 8C) and a micro lens array 902 (see FIG. 9). In embodiments, the FCC 801 may be configured as an acceleration lens (V_{FCC}>zero (GND)) or deceleration lens (V_{FCC}<zero (GND)).

FIG. 8C illustrates a schematic top view 850 of the conducive plate 810, in accordance with one or more embodiments of the present disclosure. The conductive plate 810 may include a set of holes 812 with the conductive plate 810 operating as a ground plate. In embodiments, the set of holes may have equal diameter. In embodiments, the holes 812 may be hexagonally distributed across plate 810, with a diameter of d and a pitch of p. It is noted that the total number of electron beams in a hexagonal distribution (N_{TB}) may be addressed with the ring number (n) in FIG. 8C, given by

$${N}_{TB} = \frac{1}{4} [ 3 {( 2 n + 1 )}^{2} + 1 ] \qquad Eq . 1$$

For example, the N_{TB} is 91 and 331 with 5 rings (n=5) and 10 rings (n=10) of hexagonally distributed beams (holes), respectively.

FIG. 9 illustrates a schematic top view 900 of microlens array 902 of the FCC 801, in accordance with one or more embodiments of the present disclosure. In embodiments, the microlens array 902 includes a plurality of microlenses 904 formed on an insulative plate 906. In embodiments, the plurality of microlenses 904 are arranged in a hexagonal pattern to match the hexagonal pattern of the holes 812 of the conductive plate 810. In embodiments, each microlens 904 of the microlens array 902 is formed by conductively coating an area 910 around a hole 908 within the insulative plate 906. In embodiments, the inner diameter of one or more micro lenses 904 may be selected to equal to the diameter (d) of the holes 812 within the conductive plate 810. In addition, the outer diameter of a respective micro lens 904 may be selected to optimize multiple conditions. For example, the outer diameter may be selected such that sufficient gaps exist between microlenses 904 for integrating the power lines to provide each microlens voltage. In addition, the outer diameter may be selected to minimize/remove the crosstalk between microlenses 904.

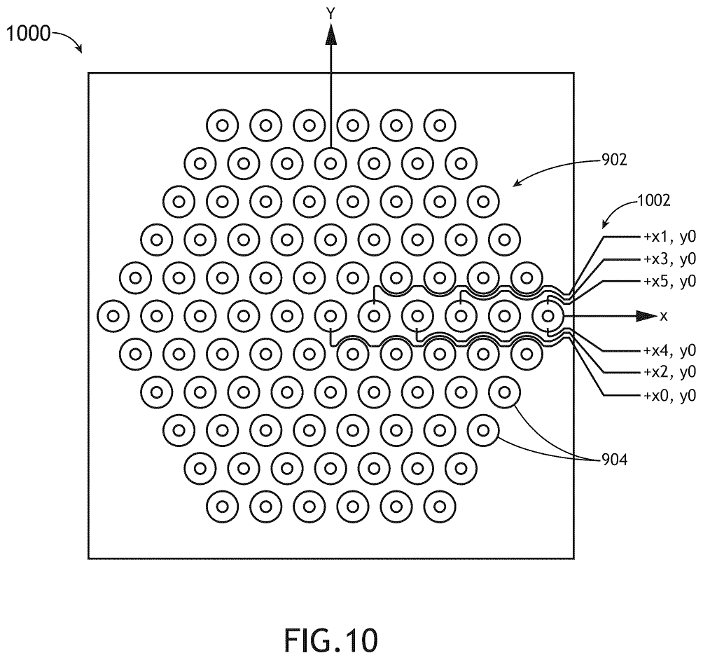

FIG. 10 illustrates a schematic top view 1000 of the microlens array 902 with power lines 1002, in accordance with one or more embodiments of the present disclosure. It is noted that FCC 801 may constitute an FCC array chip with sub-millimeter thickness and millimeter outer diameter. Inside the chip, tens-to-hundreds of microlenses are integrated, whereby each microlens may be powered (voltage-applied). In embodiments, the power lines 1002 for applying the voltages to the microlenses 904 of the microlens array 902 may be designed and buried underneath the insulation within the gaps between the micro lenses 904. For example, the micro lenses 904 on +x-axis and the corresponding power lines 1002 are addressed as (+x0,y0), (+x1,y0), (x2,y0), (+x3,y0), (+x4,y0) and (+x5,y0). By way of further example, the micro lenses 904 on +y-axis and the corresponding power lines 1002 are addressed as (+x0,y0), (+x0,y1), (x0,y2), (+x0,y3), (+x0,y4) and (+x0,y5). This procedure may be extended to each of the microlenses 904 of the microlens array 902 in both x- and y-directions.

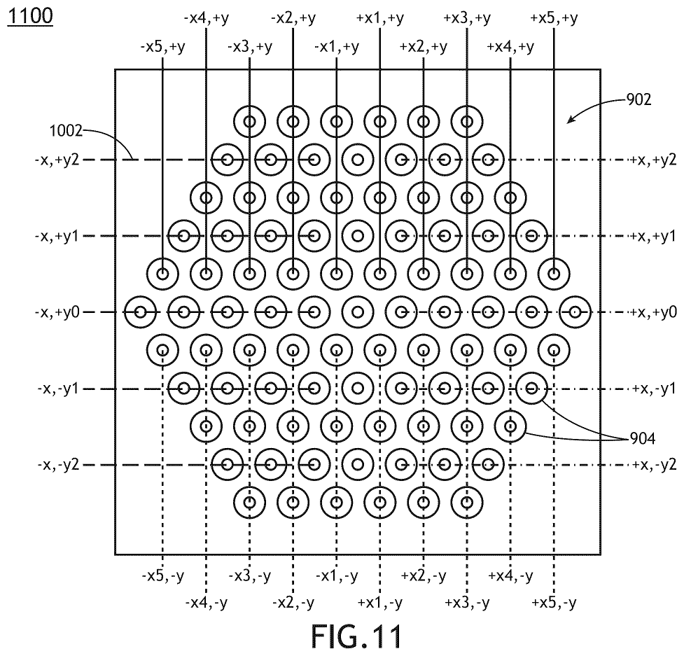

FIG. 11 illustrates a schematic top view 1100 of the microlens array 902 showing the addressing of power lines 1002, in accordance with one or more embodiments of the present disclosure. In embodiments, the power lines 1002 for all the microlenses 904 may be designed and buried underneath the insulating material formed of the insulative plate of the microlens array 902. The insulating material is located on the first surface and/or a second surface of the insulative plate. In this example, a single line in FIG. 11 represents the multi-lines in FIG. 10. For instance, the line (+x,y0) in FIG. 11 represents the lines (+x0,y0), (+x1,y0), (x2,y0), (+x3,y0), (+x4,y0) and (+x5,y0) in FIG. 10, addressing the microlenses and power lines on +x-axis. This procedure may be extended to the other microlenses and power lines as shown.

In embodiments, the power lines in +x-axis and −x-axis may be disposed on one (e.g., the top) surface of the insulating plate 906 and the power lines in the +y-axis and −y-axis may be disposed on the other (e.g. the bottom) surface of the insulating plate 906 (or vice-versa).

It is noted that with the FC-individually-corrected method, the FCC voltage on each microlens linearly varies with the off-axis distance (r). For instance, if using a voltage of 300V to correct the FC distance (Δz_{FC}) between the center beam and farthest beam in a 10-ring MEB optic, the potential difference between microlenses in FIG. 10 or FIG. 11 is 30 Volts. This potential difference of 30 Volts may be used as the reference to design the gap distance between the power lines in FIG. 10 and FIG. 11.

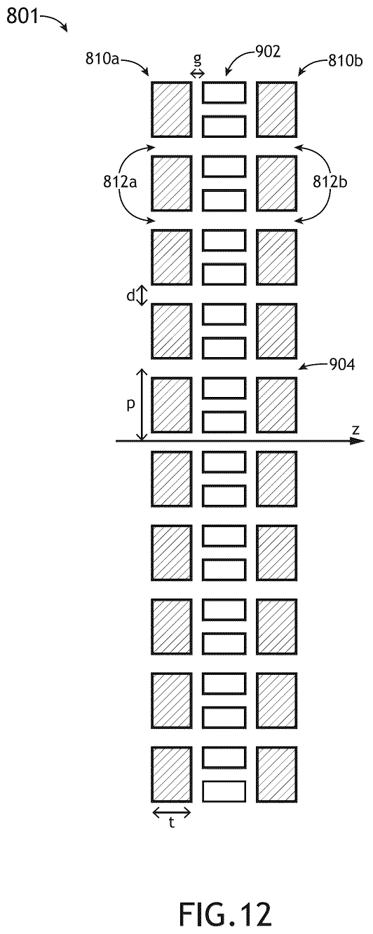

FIG. 12 illustrates a schematic view of the field curvature corrector 801, in accordance with one or more additional and/or alternative embodiments of the present disclosure. In this embodiment, the microlenses within the FCC 801 may be configured Einzel-lenses. In this regard, the FCC 801 may include an Einzel-lens-based array. It is noted that, in an Einzel lens, electrons are neither decelerated nor accelerated before entering and after leaving the microlens array. In this embodiment, the FCC 801 includes an additional conductive plate 810b (i.e., ground plate) which corresponds to the first conductive plate 810a. In embodiments, the additional conductive plate 810b also includes a set of holes 812b arranged in a hexagonal array that corresponds with the hexagonal array of holes 812a. In embodiments, the additional conductive plate 810b is positioned at a side of the insulative plate 902 opposite of the first conductive plate 810a, thereby forming a stack of including conductive plate/microlens array/conductive plate. This arrangement creates an array of micro Einzel-lenses which may be individually addressed. The thickness of the plates (t) may be tens of microns (e.g., 50 microns). The pitch between beams (p) may be a sub-millimeter distance (e.g., 100˜200 microns), and the diameter of the holes (d) may be on the order of tens of microns (e.g. 50 microns). The gap between the plates (g) may be optimized to avoid crosstalk between beams and to avoid electrical arcing between the plates 810a, 810b. As noted previously herein, the FCC voltages on microlenses 904 linearly increase with the off-axis distance of the microlens, therefore, the potential difference between microlenses is normally low (e.g., <30 Volts). According to simulation studies, d<p/3 and g<p/5 may be used as a guideline for avoiding arcing and crosstalk in the FCC chip array in FIG. 12.

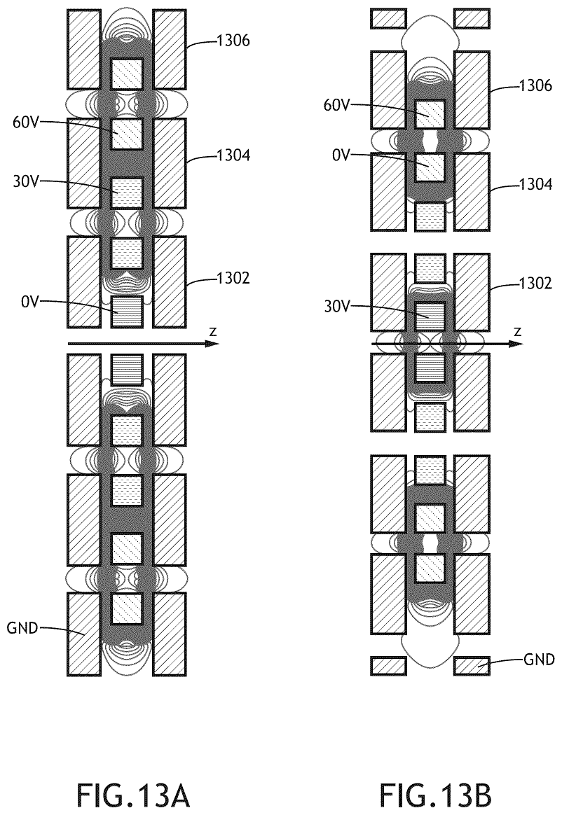

FIGS. 13A-13B illustrate simulations of electrostatic potentials to depict the avoidance of crosstalk between microlenses of the FCC 801, in accordance with one or more embodiments of the present disclosure. FIG. 13A illustrates the equipotential lines when the central ring 1302, the first ring 1304, and the second ring 1306 of the microlenses, as shown in FIG. 9, are applied with 0V, 30V and 60V voltages, respectively. The electrostatic fields around the central microlens 1302 are seen free, without being penetrated by the fields from the first ring 1304 and second ring 1306. In FIG. 13B, the central ring 1302, the first ring 1304, and the second ring 1306, as shown in FIG. 9, are applied with 30V, 0V and 60V voltages, respectively. The electrostatic fields around the first ring 1304 are seen free, without being penetrated by the fields from the central ring 1302 or the second ring 1306.

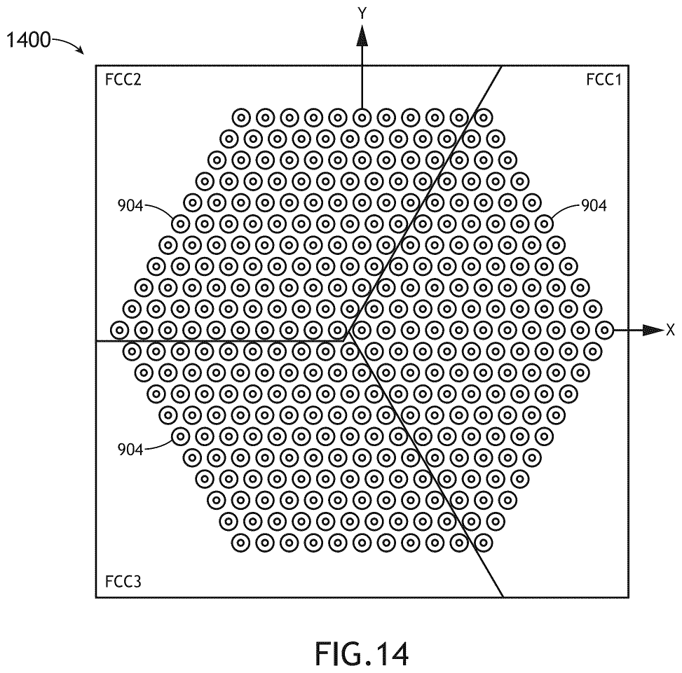

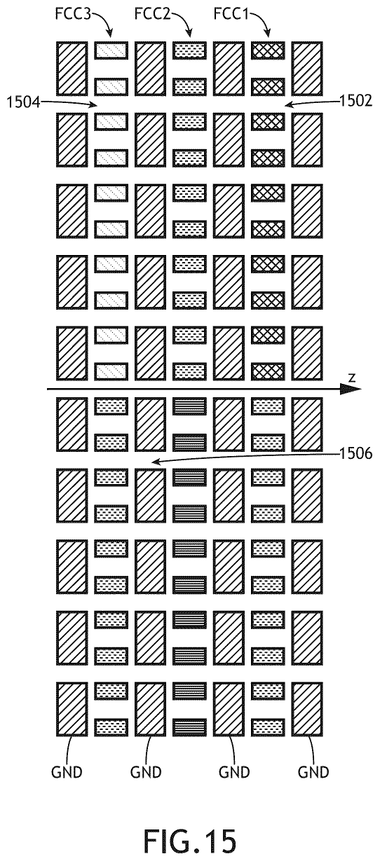

FIGS. 14 and 15 illustrate a schematic top view 1400 and a schematic side view of a set of FCCs arranged into multiple zones, in accordance with one or more additional and/or alternative embodiments of the present disclosure. It is noted that the area of the hexagon in FIG. 8C is calculated by the following:

$$S = \frac{3}{2} \sqrt{3} {p}^{2} {n}^{2} \qquad Eq . 2$$

where p is the pitch between beams and n is the number of the rings of the hexagon. In the case where the pitch is fixed according to the requirements of the given electron-beam optical architecture, the throughput is largely determined by the ring number (n) or the total beam number, N_{TB} in Eq. (1). In order to increase throughput, more and more beamlets are used, and more and more microlenses are required. This makes it more difficult to integrate the power lines shown in FIG. 10 and FIG. 11.

In embodiments, as shown in FIGS. 14 and 15, multiple stacked arrays of microlenses may be implemented to mitigate the issues of power line integration for increasing number of beamlets. In embodiments, the stack 1500, as shown in FIG. 15, includes a combination of three layers, whereby each of these layers functions similarly to the FCC 801 depicted in FIG. 12. It is noted that a microlens for correcting the field curvature of a beamlet is a fairly weak lens, and it may be deployed at any z-plane in the given optical system. As a result, each microlens may reside in a different z-plane without influencing its ability to correct the beamlet field curvature. As a result, the microlenses may be arranged in a variety of spatial combinations.

FIG. 14 illustrates one such non-limiting example. In this embodiment, a large number of microlenses 902 (e.g., n=10 and N_{TB}=331) are divided into three zones. The zones include zone FCC1, zone FCC2, and zone FCC3. In embodiments, when one of the zones is used in one layer of the stack in FIG. 15, the remaining two zones are not used and may be utilized to manage power lines of the in-use zone. For example, the zone FCC3, zone FCC2 and zone FCC1 are respectively used as the FC correction microlenses in the left layer, middle layer and right layer of the stack in FIG. 15. In this example, each layer of the stack has about two-thirds of dummy area that may be used for integrating the power lines for activating/addressing the one-third microlenses of the active area. When viewed from a top view, an entire contiguous area will be covered by the stack of three FCCs. In this regard, it is noted that the active areas FCC1, FCC2, and FCC3 of FIG. 14 do not reside within the same plane and are offset in the z-direction. Correspondingly, the active portions 1502, 1504, and 1506 of FCC1, FCC2, and FCC3 respectively of FIG. 15 do not overlap with each other in the x-y plane, but rather form a contiguous set of active areas as shown in FIG. 14.

It is noted that the configuration depicted in FIGS. 14 and 15 are not limiting on the scope of the present disclosure as various spatial arrangements, number of active zones, and number of FCCs are within the scope of the present disclosure. For example, there are many other approaches to dividing the zones of microlenses 902. For instance, the FCC zones may correspond to different rings of microlenses 902. By way of non-limiting example, FCC1 may correspond to the 0^{th}/3^{rd}/6^{th}/9^{th} rings, while FCC2 corresponds to the 1^{st}/4^{th}/7^{th}/10^{th} rings, and FCC3 corresponds to the 2^{nd}/5^{th}/8^{th} rings in FIG. 14 accounting for 331 beams. In another example, the stack 1400 may include more than three layers, which would allow for even higher throughputs with more beams (more zones of microlenses). The stack configuration of FIGS. 14 and 15 may include any number of layers with the zones delineated in any number of geometrical arrangements.

Referring again to FIGS. 8A-15, embodiments and various components are described in additional detail.

In embodiments, the MEB imaging system may include a sample stage (not shown). The sample stage may include any sample stage known in the art of electron-beam microscopy. In embodiments, the sample stage is an actuatable stage. For example, the sample stage may include, but is not limited to, one or more translational stages suitable for selectably translating the sample 816 along one or more linear directions (e.g., x-direction, y-direction and/or z-direction). By way of another example, the sample stage 816 may include, but is not limited to, one or more rotational stages suitable for selectively rotating the sample 816 along a rotational direction. By way of another example, the sample stage may include, but is not limited to, a rotational stage and a translational stage suitable for selectably translating the sample along a linear direction and/or rotating the sample 816 along a rotational direction.

The sample 816 may include any sample suitable for characterization (e.g., inspection or review) with electron-beam microscopy. In embodiments, the sample 816 includes a wafer, die, chip, reticle, flat panel display, or the like. For example, the sample may include, but is not limited to, a semiconductor wafer.

In embodiments, the MEB imaging system 800 includes a detector assembly (not shown). The detector assembly may include any type of electron detector assembly or detector array known in the art configured to detect electrons (e.g., secondary and/or backscattered electrons). For example, detector assembly may collect and image SEs using an Everhart-Thornley detector (or other type of scintillator-based detector). In another embodiment, SEs may be collected and imaged using a micro-channel plate (MCP). In another embodiment, electrons may be collected and imaged using a PIN or p-n junction detector, such as a diode or a diode array. In another embodiment, electrons may be collected and imaged using one or more avalanche photo diodes (APDs).

In embodiments, the microlenses 904 of the microlens array 902 may be addressed utilizing a controller (not shown). The controller may include one or more processors communicatively coupled to memory, where the one or more processors may be configured to execute a set of program instructions maintained in memory, and the set of program instructions may be configured to cause the one or more processors o carry out various functions and steps of the present disclosure.

In embodiments, the one or more processors include any one or more processing elements known in the art. In this sense, the one or more processors may include any microprocessor-type device configured to execute software algorithms and/or instructions. In embodiments, the one or more processors may consist of a desktop computer, mainframe computer system, workstation, image computer, parallel processor, or other computer system (e.g., networked computer) configured to execute a program configured to operate the MEB imaging system 800, as described throughout the present disclosure. It should be recognized that the steps described throughout the present disclosure may be carried out by a single computer system or, alternatively, multiple computer systems. Furthermore, it should be recognized that the steps described throughout the present disclosure may be carried out on any one or more of the one or more processors. In general, the term “processor” may be broadly defined to encompass any device having one or more processing elements, which execute program instructions from memory 208.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” “downward”, “X direction”, “Y direction” and the like are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

Finally, as used herein any reference to “in embodiments, “one embodiment”, “some embodiments”, or the like means that a particular element, feature, structure, or characteristic described in connection with the embodiment is included in at least one embodiment disclosed herein. The appearances of the phrase “in embodiments” in various places in the specification are not necessarily all referring to the same embodiment, and embodiments may include one or more of the features expressly described or inherently present herein, or any combination of sub-combination of two or more such features, along with any other features which may not necessarily be expressly described or inherently present in the instant disclosure.

What is claimed:

1. A multi-beam electron imaging apparatus comprising:
an electron beam source configured to generate a telecentric primary electron beam;
a micro-beam creation array configured to split the telecentric primary electron beam into a set of telecentric electron beamlets, wherein the micro-beam creation array comprises:
a field curvature corrector, wherein the field curvature corrector is configured to individually correct field curvature blur of each telecentric beamlet, wherein the field curvature corrector comprises:
a conductive plate, wherein the conductive plate includes a plurality of holes arranged in a hexagonal array; and
a microlens array, wherein the microlens array includes a plurality of microlenses formed on an insulative plate, wherein the plurality of microlenses are arranged in a hexagonal pattern to match the hexagonal pattern of the holes of the conductive plate,
wherein the microlens array includes a plurality of power lines for individually addressing each of the microlenses of the microlens array; and
a set of electron optics configured to focus the set of telecentric electron beamlets onto a sample for inspection of the sample.

2. The multi-electron-beam imaging system of claim 1, wherein the micro-beam creation array further comprises:
an aperture array;
a micro deflector array; and
a micro stigmator array.

3. The multi-electron-beam imaging system of claim 1, further comprising a detector assembly configured to detect electrons from the sample.

4. The multi-electron-beam imaging system of claim 1, wherein each microlens of the microlens array is formed by conductively coating an area around a hole within the insulative plate.

5. The multi-electron-beam imaging system of claim 1, wherein each microlens of the microlens array is configured to operate as at least one of an acceleration lens or a deceleration lens.

6. The multi-electron-beam imaging system of claim 1, wherein an inner diameter of at least some of the microlenses of the microlens array is equal to a diameter of at least some of the holes of the conductive plate.

7. The multi-electron-beam imaging system of claim 1, wherein the power lines of the plurality of power lines of the micro-lens array are disposed beneath insulating material of the insulative plate of the microlens array, wherein the insulating material is located on at least one of a first surface or a second surface of the insulative plate.

8. The multi-electron-beam imaging system of claim 7, wherein powerlines associated with a first direction are disposed beneath insulating material of a first surface of the insulative plate and powerlines associated with a second direction are disposed beneath insulating material of a second surface of the insulative plate.

9. The multi-electron-beam imaging system of claim 1, wherein the field curvature corrector comprises an additional a conductive plate, wherein the additional conductive plate includes a plurality of holes arranged in a hexagonal array, wherein the additional conductive plate is positioned at a side of the insulative plate opposite of the conductive plate, wherein the conductive plate, the microlens array, and the additional conductive plate are configured such the microlenses of the microlens array operate as Einzel lenses.

10. A multi-electron-beam imaging system comprising:
an electron beam source configured to generate a telecentric primary electron beam;
a micro-beam creation array configured to split the telecentric primary electron beam into a set of telecentric electron beamlets, wherein the micro-beam creation array comprises:
a field curvature stack, wherein the field curvature stack comprises a plurality of field curvature correctors, wherein each field curvature corrector comprises:
a conductive plate, wherein the conductive plate includes a plurality of holes arranged in a hexagonal array; and
a microlens array, wherein the micro-lens array includes a plurality of microlenses formed on an insulative plate, wherein the plurality of microlenses are arranged in a hexagonal pattern to match the hexagonal pattern of the holes of the conductive plate,
wherein each of the field curvature correctors includes one or more dummy portions and one or more active inspection areas of microlenses, wherein a stacked configuration of the plurality of field curvature correctors along a z-direction forms a contiguous active inspection area of microlenses along the x-direction and y-direction; and
a set of electron optics configured to focus the set of telecentric electron beamlets onto a sample for inspection of the sample.

11. The multi-electron-beam imaging system of claim 10, wherein the microlenses of the microlens array are configured as Einzel lenses.

12. The multi-electron-beam imaging system of claim 10, wherein the micro-beam creation array further comprises:
an aperture array;
a micro deflector array; and
a micro stigmator array.

13. The multi-electron-beam imaging system of claim 10, further comprising a detector assembly configured to detect electrons from the sample.

14. The multi-electron-beam imaging system of claim 10, wherein each microlens of the microlens array is formed by conductively coating an area around a hole within the insulative plate.

15. A field curvature correction apparatus comprising:
a conductive plate, wherein the conductive plate includes a plurality of holes arranged in a hexagonal array; and
a microlens array, wherein the microlens array includes a plurality of microlenses formed on an insulative plate, wherein the plurality of microlenses are arranged in a hexagonal pattern to match the hexagonal pattern of the holes of the conductive plate,
wherein the microlens array includes a plurality of power lines for individually addressing each of the microlenses of the microlens array to individually correct field curvature blur of individual electron beamlets.

16. The field curvature correction apparatus of claim 15, wherein each microlens of the microlens array is formed by conductively coating an area around a hole within the insulative plate.

17. The field curvature correction apparatus of claim 15, wherein each microlens of the microlens array is configured to operate as at least one of an acceleration lens or a deceleration lens.

18. The field curvature correction apparatus of claim 15, further comprising an additional conductive plate, wherein the additional conductive plate includes a plurality of holes arranged in a hexagonal array, wherein the additional conductive plate is positioned at a side of the insulative plate opposite of the conductive plate, wherein the conductive plate, the microlens array, and the additional conductive plate are configured such the microlenses of the microlens array operate as Einzel lenses.

19. A field curvature correction apparatus comprising:
a plurality of field curvature correctors arranged in a stack, wherein each field curvature corrector comprises:
a conductive plate, wherein the conductive plate includes a plurality of holes arranged in a hexagonal array; and
a microlens array, wherein the micro-lens array includes a plurality of microlenses formed on an insulative plate, wherein the plurality of microlenses are arranged in a hexagonal pattern to match the hexagonal pattern of the holes of the conductive plate,
wherein each of the field curvature correctors includes one or more dummy portions and one or more active inspection areas of microlenses, wherein a stacked configuration of the plurality of field curvature correctors along a z-direction forms a contiguous active inspection area of microlenses along the x-direction and y-direction.

20. The field curvature correction apparatus of claim 19, wherein the microlenses of the microlens array are configured as Einzel lenses.
